(19) United States
(12) Patent Application Publication
(10) Pub. No.: US 2009/0127608 A1
(43) Pub. Date: May 21, 2009

(54) INTEGRATED CIRCUIT AND METHOD OF MANUFACTURING AN INTEGRATED CIRCUIT

(76) Inventor: Rolf Weis, Dresden (DE)

Correspondence Address: Thomas G. Eschweiler, Esq.;Eschweiler & Associates, LLC, Suite 1000, 629 Euclid Avenue, Cleveland, OH, 44114, US

(21) Appl. No.: 11/943,482

(22) Filed: Nov. 20, 2007

(51) Int. Cl. H01L 27/108; H01L 21/8242

(52) U.S. Cl. 257/306; 438/129; 257/E27.084; 257/E21.648

(57) ABSTRACT

An integrated circuit including a memory cell array is shown. The memory cell array comprises word lines extending in a first direction and bit lines extending in a second direction intersecting the first direction and memory cells. The memory cells may include storage elements, bit line contacts for coupling a corresponding memory cell to a corresponding bit line. The bit line contacts are arranged in a checkerboard pattern with respect to the first direction, and the storage elements are arranged in a regular grid along the first and second directions, respectively.

### FIELD OF THE INVENTION

This specification relates to an integrated circuit having a memory cell array.

### BACKGROUND OF THE INVENTION

Memory cells of a dynamic random access memory (DRAM) type generally have a storage capacitor for storing an electrical charge that represents an information to be stored, and an access transistor that is connected with a storage capacitor. A memory cell array further includes word lines that are connected to the gate electrodes of corresponding transistors. Moreover, a memory cell array further includes bit lines that are connected to corresponding a doped portions of the transistors.

When further shrinking the feature size of integrated circuits, problems related to manufacturability may be arise.

Therefore, there is a need for an integrated circuit that will solve the above problems.

### BRIEF DESCRIPTION OF THE DRAWINGS

The accompanying drawings are included to provide a further understanding of embodiments of the invention and are incorporated in and constitute a part of this specification.

FIG. 1 shows a schematic plan view of a memory cell array in accordance with the invention;

FIG. 2 shows an equivalent circuit diagram of a memory device in accordance with the invention;

FIGS. 3A to 3D show various cross-sectional views of a memory cell array according to the invention;

FIG. 4 shows a cross-sectional view of a transistor which may be disposed in the support portion;

FIG. 5 shows a schematic plan view of a memory cell array according to another embodiment;

FIGS. 6A and 6B show views of a memory cell array according to another embodiment;

FIG. 7 shows a flowchart illustrating a method according to an embodiment;

FIG. 8 shows a plan view of a substrate when performing a method according to an embodiment;

FIGS. 9A to 9C show various views of a substrate when performing a method according to an embodiment;

FIGS. 10A and 10B show various views of a substrate after depositing a spacer;

FIGS. 11A and 11B show views of a substrate after forming a sacrificial layer;

FIG. 12 shows a cross-sectional view of a substrate after a further processing step;

FIGS. 13A and 13B show cross-sectional views of a substrate after performing a further processing step;

FIGS. 14A to 14D show various views of a substrate after performing a further processing step;

FIGS. 15A to 15D show various views of a substrate after performing a further processing step;

FIGS. 16A and 16B show various views of a substrate after forming a gate dielectric layer;

FIGS. 17A to 17E show views of a substrate after forming a conductive layer;

FIGS. 18A to 18C shows views of a substrate after forming a dielectric layer;

FIGS. 19A to 19E show view of a substrate after patterning a layer stack;

FIGS. 20A to 20C show view-s of a substrate after forming a further sacrificial layer;

FIGS. 21A to 21C show views of a substrate after patterning a layer stack;

FIG. 22 shows a cross-sectional view of a substrate after forming a further spacer;

FIG. 23 shows a cross-sectional view of the substrate after forming a bit line;

FIG. 24 shows a cross-sectional view of the substrate after forming further spacers; and

FIGS. 25A and 25B show views of the substrate after forming a storage capacitor.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The drawings illustrate the embodiments of this invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

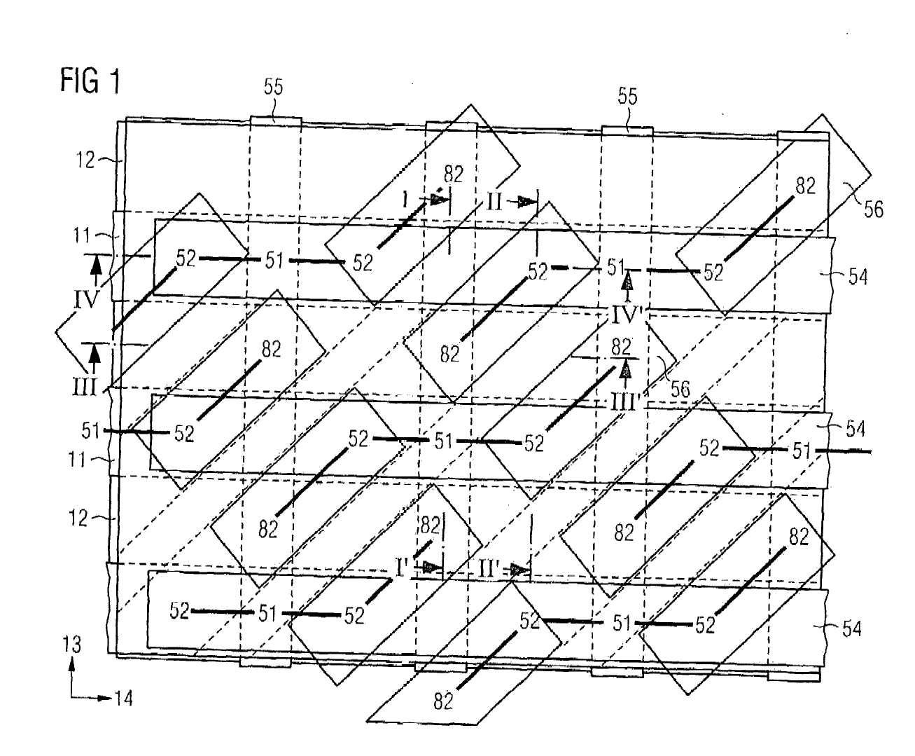

FIG. 1 shows a plan view of an integrated circuit comprising a memory cell array. As is shown, a plurality of isolation trenches 12 are formed in a suitable substrate.

The terms “wafer”, “substrate”, “semiconductor chip” or “semiconductor substrate” used in the context of within this description may include any semiconductor-based structure that has a semiconductor substrate. Wafer and substrate are to be understood to include silicon, silicon-on-insulator (SOI), silicon-on-sapphire (SOS), doped and undoped semiconductors; epitaxial layers of silicon supported by a base crystalline material, and other semiconductor structures. The semiconductor need not be silicon-based. The semiconductor could as well be, among others, silicon-germanium, germanium or gallium arsenide. Various components may already be formed in the substrate. Moreover, different layers may be embedded in the substrate material.

The isolation trenches may be filled with a suitable insulating material or a combination thereof. The isolation trenches 12 extend along a second direction 14. Between adjacent isolation trenches 12, active area lines 11 are formed. As is clearly to be understood, the active areas may have an arbitrary shape. For example, the active areas may be formed so as to extend as lines or segments of lines or as elongated holes. The active areas 11 also extend in the second direction 14. In each of the active areas, transistors 15 are formed. The transistors 15 are connected with corresponding storage elements such as storage capacitors 82 via a node contact 52 and a capacitor contact 53. Moreover, the transistors 15 are connected with a corresponding bit line 54 via a bit line contact 51. As is shown in FIG. 1, two neighboring transistors 15 may share a common bit line contact 51 so as to be connected with the bit line 54. Each of the transistors 15 comprises a first and second source/drain portion 21,22 as well as a channel 23 which is disposed between the first and the second source/drain portion 21,22. The first source/drain portion 21 is in contact with the node contact 52. Moreover, the second source/drain portion 22 is in contact with the bit line contact 51.

The memory cell array shown in FIG. 1 comprises bit lines 54, which may extend in the second direction 14, as well as word lines 55 which may extend in the first direction 13. In the layout shown in FIG. 1, the transistors 51 are arranged so ht a component of a channel of each of the transistors extends in the second direction 14. Moreover, a line connecting a first source/drain portion 21 and a storage element 82 extends in a direction which intersects be first; and the second directions.

An integrated circuit may include a memory cell array comprising word lines 55 extending in a first direction 13 and bit lines 54 extending in a second direction 14 intersecting the first direction 13. The memory cells 16 may further include storage elements 82 such as storage capacitors. The memory cell array further comprises bit line contacts 51 that are in signal connection with a memory cell 16 and a corresponding bit line 54. As is shown in FIG. 1, for example, the bit line contacts 51 are arranged in a checkerboard pattern with respect to the first direction 13. Moreover, the storage elements 82 are arranged in a regular grid along the first and second directions, respectively. Accordingly, by this arrangement, a memory cell array having a higher packaging density and an increased degree of miniaturization may be obtained.

In the context of the present specification the term “in signal connection with” means that a first component is electrically connected with a second component. Accordingly, electrical signals may be transmitted from the first to the second component and vice versa. The first and the second component need not be in physical contact with each other. Accordingly, a further component may be disposed between the first and the second components, while electrical signals may be transmitted between the first and the second components.

Moreover, the bit line contacts 51 are disposed in rows so that the bit line contacts of every row having an even row number are disposed in a space between two adjacent bit line contacts of every row having an uneven row number and vice versa. Moreover, the storage elements 82 are disposed in rows and columns. The distance between adjacent storage elements 82 measured along the first direction 13 need not be equal to the distance between the storage elements 82 of one row measured along the second direction. As is further shown in FIG. 1, each of the transistors 15 comprises a first source/drain portion 21 and a second source/drain portion 22. The node contacts 52 may be implemented as sections of a rewiring layer 56 to connect one of the storage elements 82 with a corresponding first source/drain portion 21. As can be taken from FIG. 1, the sections of the rewiring layer 56 may be implemented as segments of parallel lines. For example, these parallel lines may extend in a direction which intersects the first direction 13 and the second direction 14.

The integrated circuit shown in FIG. 1 includes a memory cell array comprising bit lines 54 extending in the second direction 14 and memory cells 16 comprising transistors 15, each of the transistors 15 comprising a channel 23. A current flowing in the channel 23 comprises a directional component extending along the second direction 14. The transistor 15 further comprises a first source/drain portion 21 and, optionally, node contacts 52 or coupling the transistor 15 to a corresponding storage element 82. As is shown in FIG. 1, the first source/drain portions 21 may be arranged in a regular grid along the first direction. Accordingly, the first source/drain portions 21 are arranged in rows extending along the second direction and in columns extending along the first direction as has been explained above.

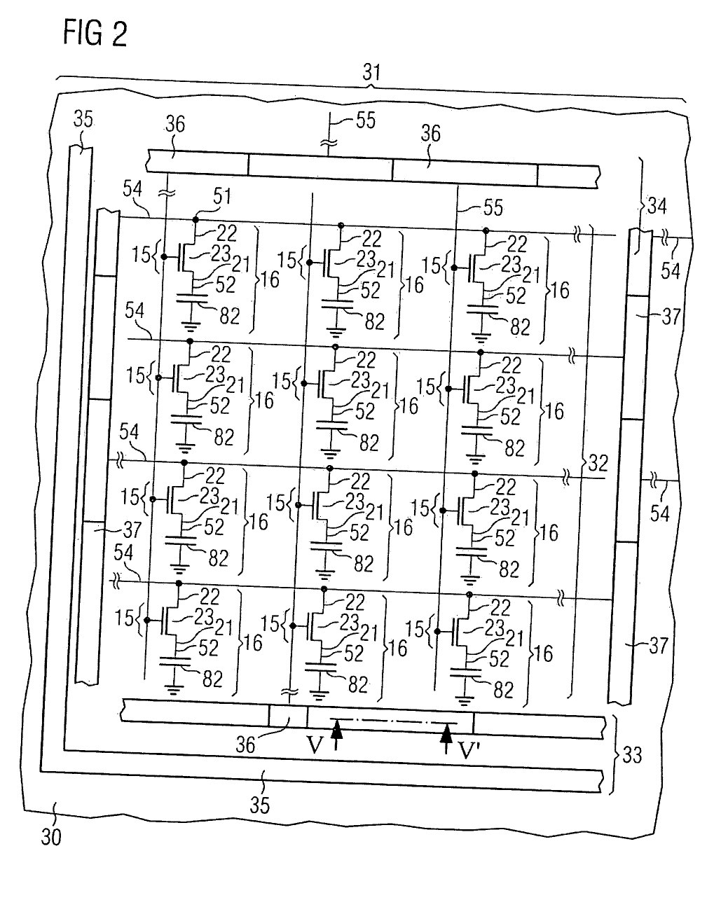

FIG. 2 shows an equivalent circuit diagram of an integrated circuit according to an implementation of the invention. The integrated circuit 30 comprises a memory device 31. The memory device 31 comprises a memory cell array portion 32 and a support portion 33. The memory cell array portion 32 may comprise memory cells 16 as has been, for example, explained above with reference to FIG. 1. Moreover, the memory cell array may comprise word lines 55 and bit lines 54. A memory cell 16 may comprise a storage element 82 such as a storage capacitor as well as an access transistor 15. For example, the access transistor 15 may be connected to the storage element 82 via a node contact 52. The transistor 15 may be implemented in the manner as has been explained above and will be shown in the following Figures. Furthermore, the access transistor 15 may be connected to a corresponding bit line 54 via a corresponding bit line contact 51. The support portion 33 may comprise a core circuitry 34 as well as a peripheral portion 35. By way of example, the core circuitry 34 may comprise word line drivers 36 as well as sense amplifiers 37. For example, a specific word line 55 may be activated by addressing a corresponding word, line driver 36. Accordingly, the information of all the memory cells that are connected with a single word line 55 may be read out via the bit lines 54. The signals transmitted by a bit line 54 may be amplified in the sense amplifiers 37. For example, in the support portion 33, transistors may be present. The memory device 31 may be implemented in any arbitrary architecture including open bitline architecture and others which are generally known in the art.

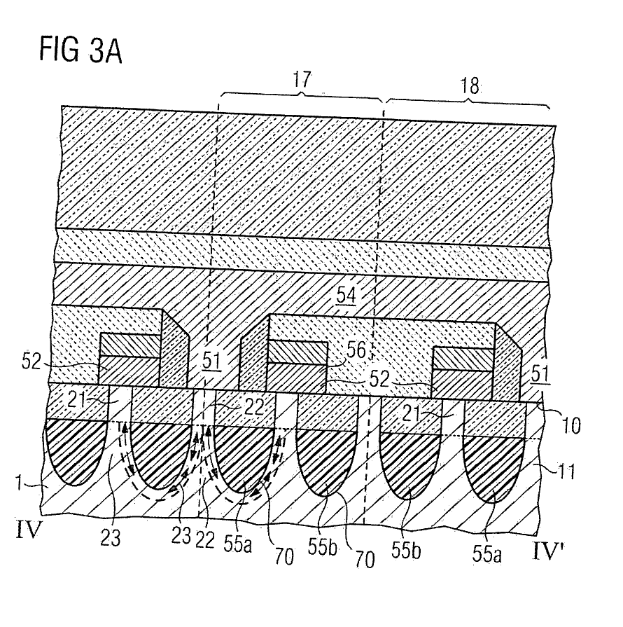

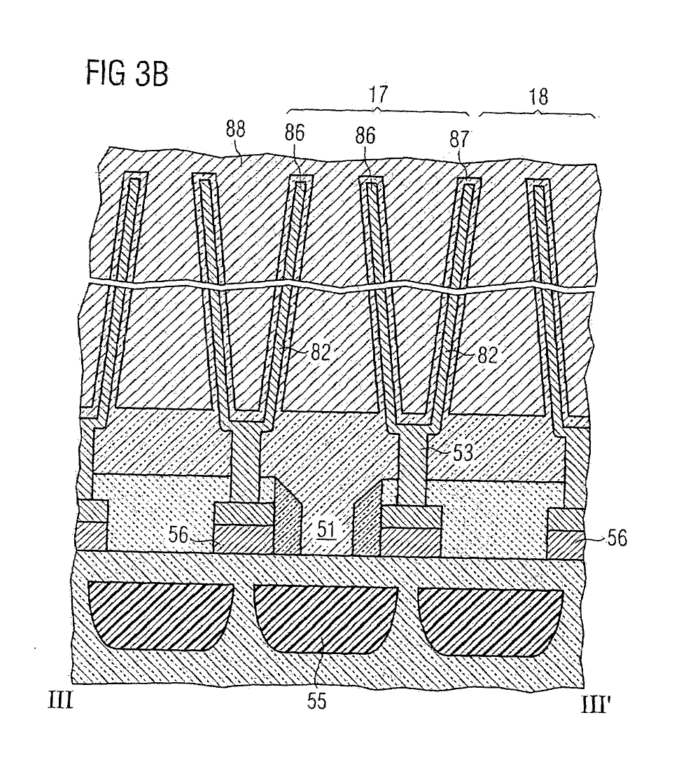

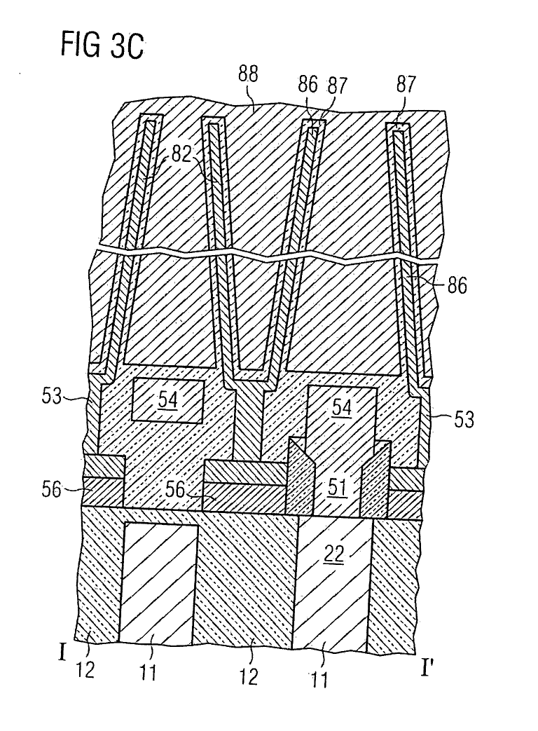

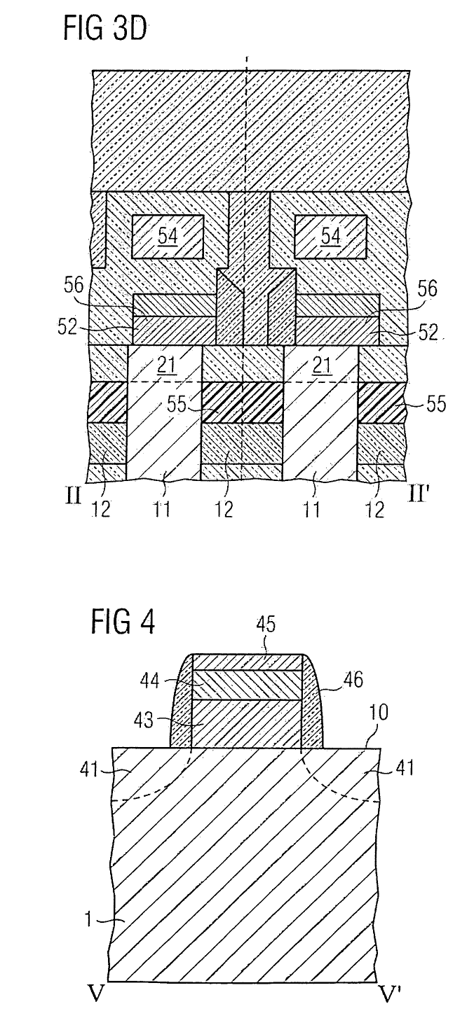

FIG. 3A shows a cross-sectional view of a substrate including an integrated circuit between IV and IV′ as is shown in FIG. 1, for example. For example, each of the transistors comprises a first and a second source/drain portion 21, 22. A first gate electrode 55a is disposed adjacent to a substrate surface 10 between the first and the second source/drain portions 21, 22. Moreover, a second gate electrode 55b is provided. The second gate electrode 55b is in electrical contact with a first gate electrode 55a in a plane lying before or behind the illustrated plane of the drawing. The first and the second gate electrode are arranged on opposite sides of the first source/drain portion. The gate electrode 55 is adjacent to two opposite sides of the channel 23 in the cross-sectional view between IV and IV′ which is taken along the second direction.

Furthermore, as is shown in FIG. 3A, along an active area 11, neighboring transistors 17, 18 are shown. Each of the transistors 17, 18 comprises a first and a second source/drain portion. As can be seen, a first gate electrode 55a is disposed between the first and the second source/drain portions. Moreover, a second crate electrode 55b is disposed between the first source/drain portion or the first transistor 17 and the second gate electrode 55b of the second transistor 18. Moreover, the first and the second gate electrode of each of the first and second transistors are in contact with each other. As is further shown in FIG. 3A, the bit lines 54 need not necessarily be in contact with the substrate surface 10. For example, as is shown, a bit line contact 51 may be provided so as to be in signal connection with the second source/drain portion 22 and the bit line 54. The bit line 54 may be disposed in a layer laying over the bit line contact 51. Moreover, as is shown in FIG. 3A, the bit lines 54 may also be disposed in a layer line over the rewiring layer 56.

FIG. 3B shows a further cross-sectional view of a substrate comprising an integrated circuit. The integrated circuit comprises memory cells 16 including storage capacitors 82. The cross-sectional view of FIG. 3B is taken between III and III′, as is shown in FIG. 1, for example. As is shown in FIG. 3B, the storage capacitors 82 may be connected with sections of the rewiring layer 56 via a capacitor contact 53. The sections of the rewiring layer 56 are in signal connection with corresponding first source/drain portions 21 of the transistors 15. The specific implementation of the storage capacitor 82 may be arbitrary. To be more specific the storage capacitor may be formed so as to have an arbitrary shape, not being limited to the shape shown in FIG. 3B.

As is shown in FIGS. 3A and 3B in combination with FIG. 1, the integrated circuit including a memory cell array comprises word lines and node contacts. Adjacent word lines are insulated from each other. The word lines include slotted portions, in which the word lines comprise a first and second portion 55a, 55b. The first and the second portions 55a, 55b are disposed on opposite sides or a corresponding node contact 52, respectively. Accordingly, the slotted portions of the word lines are disposed in the active areas of the memory cell array. Moreover, these two slotted portions may be merged in the isolation trenches 12, so that the two word lines may be only temporarily slotted at predetermined portions. At other portions the two portions of the word lines may be merged so as to form a single word line portion. Nevertheless, as will be explained later in greater detail. The two word lines may as well be arranged in an isolated arrangement. For example, the two word lines may be isolated in the array portion or in the center of the array portion. The two word lines may be merged at the edge of the array portion or in the peripheral portion.

Moreover, FIG. 3C shows a cross-sectional view of the substrate between I and I′, as is shown in FIG. 1, for example. As can be seen, active areas 11 are formed, adjacent active areas been separated from each other by isolation trenches 12. Moreover, bit lines 54 extend perpendicularly with respect to the plane of the drawing. The storage capacitors 82 are connected by capacitor contacts 53 to sections of a rewiring layer 56. The storage capacitors 82 may comprise a storage electrode 86, a capacitor dielectric 87 and a counter electrode 88. These components may be implemented in a manner as is generally well known in the art.

Moreover, FIG. 3D shows a cross-sectional view between II and II′, as can be, for example, taken from FIG. 1. As can be seen, a node contact 52 and the section of the rewiring layer 56 are formed adjacent to the first source/drain portions 21.

Moreover, FIG. 4 shows a cross-sectional view of an example of a transistor 47 which may be disposed in the support portion. The cross-sectional view of FIG. 4 is taken between V and V′, for example, as is shown in FIG. 2. The transistor shown in FIG. 4 comprises doped source/drain portions 49 as well as a gate electrode 43 which is disposed between the doped portions 41. The gate electrode 43 may comprise one or more conductive layers. For example, the gate electrode may comprise a polysilicon layer, followed by metallic layer 44. On top of the conductive material, a capping layer 45 may be provided. By way of example, components of the gate electrode may be made of layers which are also present in the array portion. Moreover, sidewall spacers 46 may be disposed on the sidewalls of the gate electrode 43. The doped source/drain portions 41 may be disposed adjacent to the substrate surface 10. The gate electrode 43 may comprise the same layers as the rewiring layer 56 which is shown in FIGS. 1 and 3A to 3D, respectively. Accordingly, the gate electrode 43 of the peripheral transistor 47 as well as the sections of the rewiring layer 56 may be processed by common processing steps.

Moreover, FIG. 5 shows a plan view of a memory cell array which is similar to the array shown in FIG. 1. Accordingly, a detailed description of this Figure is omitted for the sake of simplicity. As can be seen, the memory cell array comprises bit lines 54 extending in a second direction 14, memory cells 16 comprising transistors 15, each of the transistors comprising a channel 23 comprising a directional component extending along a second direction 14, capacitor contacts 53 for coupling the transistor 15 to a corresponding storage element 82. The capacitor contacts 53 are arranged in a regular grid along the second direction 14.

Nevertheless, in FIG. 5 the capacitor contacts are arranged in a regular grid. The storage capacitors 82 may be arranged in an arbitrary arrangement. For example, the storage capacitors may be as well arranged in a regular grid. Moreover, they maxi be shifted. Alternatively, they may be disposed in a hexagonal arrangement or in any other suitable arrangement. For example, the arrangement may be selected so as to enable a high packaging density.

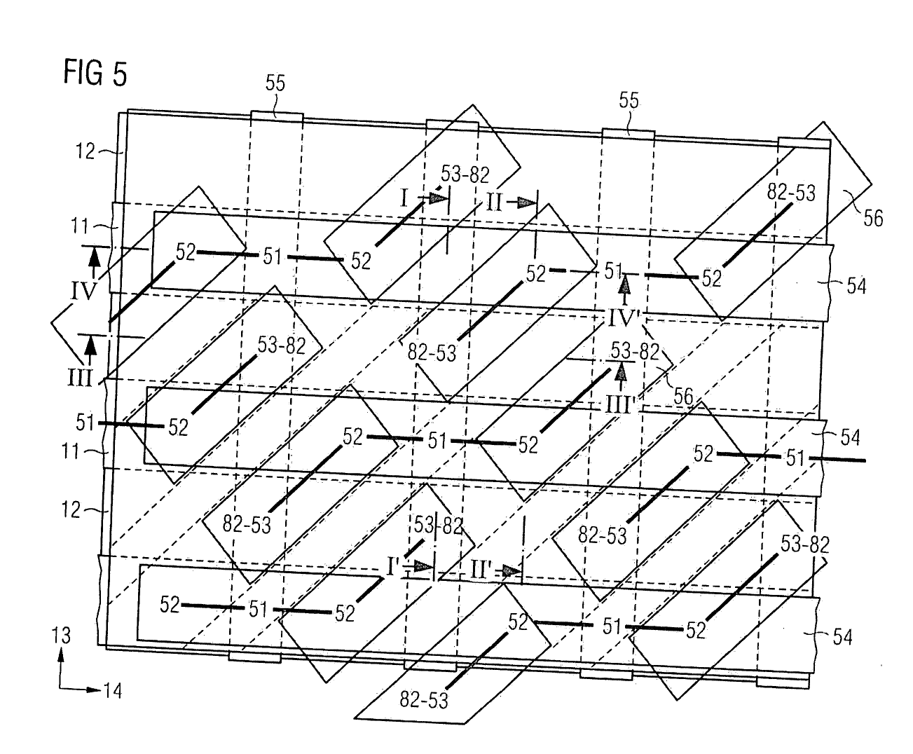

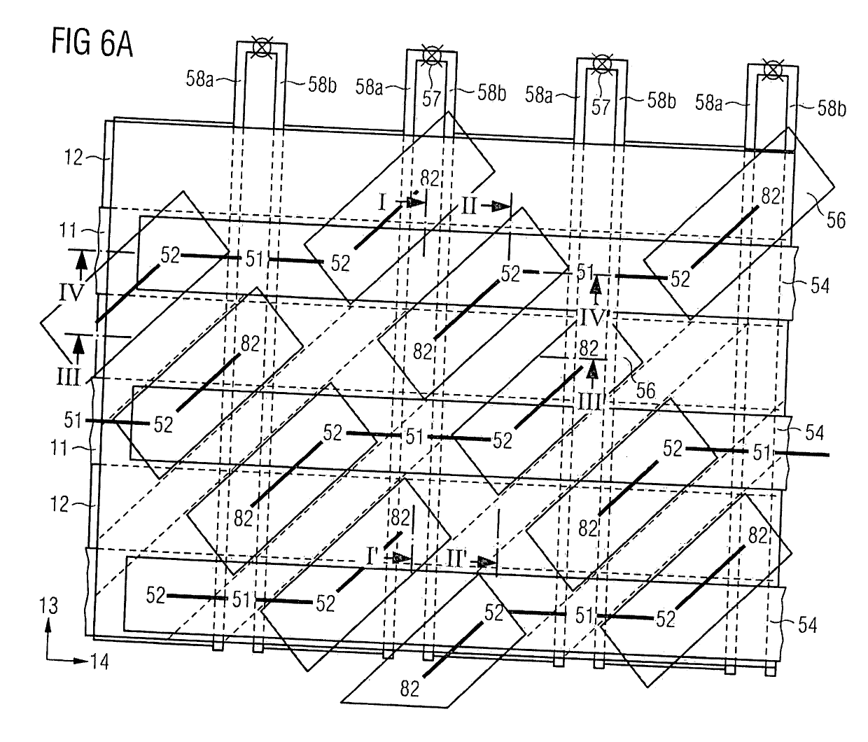

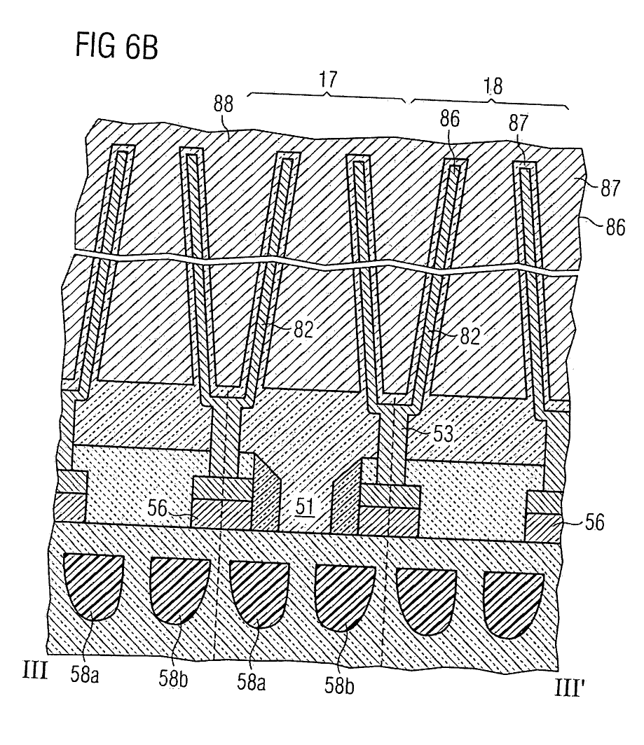

FIG. 6A shows a plan view of a memory cell array which is similar to the view shown in FIG. 1. Accordingly, a detailed description of this Figure is omitted for the sake of simplicity. According to the modification shown in FIG. 6A, the first and second gate electrodes 55a, 55b form part of corresponding first and second conductive lines 58a, 58b, which are implemented as adjacent word lines. The adjacent word lines are isolated from each other, and are configured to be held at the same potential. The two adjacent word lines 58a, 58b are disposed on opposite sides of a corresponding node contact 51, respectively. By way of example, word line contacts 57 may be disposed at the edge of the memory cell array or in the support portion so as to provide a contact of the adjacent word lines 58a, 58b. Accordingly, the adjacent word lines 58a, 58b may be held at the same potential.

FIG. 6B shows a cross-sectional view of the memory cell array which is taken between III and III′ according to this modification. This cross-sectional view corresponds to the view shown in FIG. 3B, wherein the two adjacent word lines 58a, 58b are formed as isolated word lines.

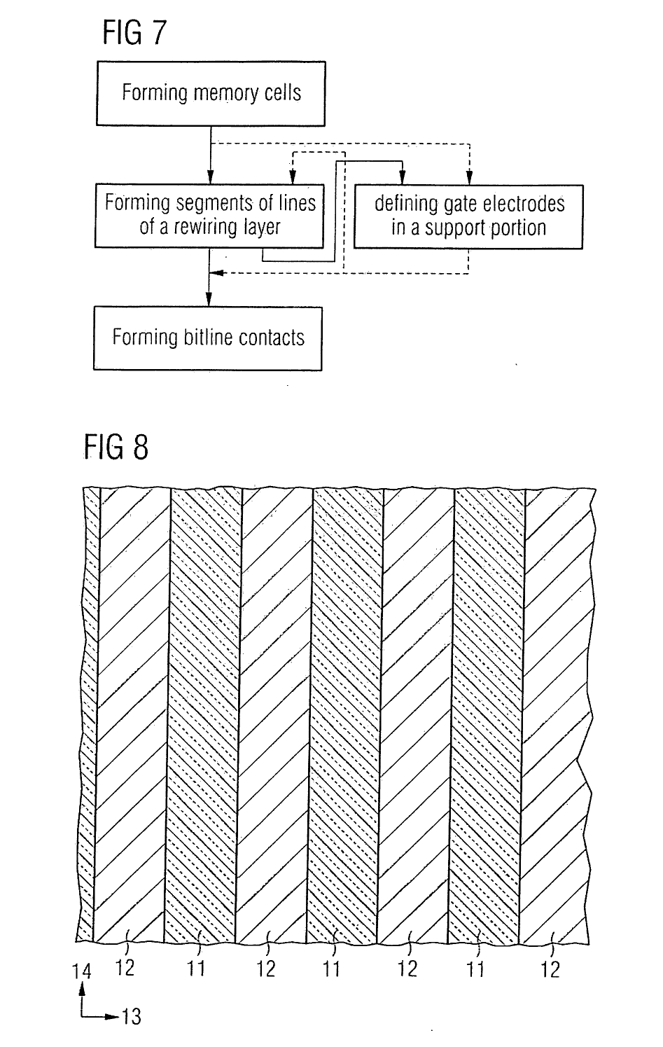

Moreover, FIG. 7 shows a schematic representation of a method according to an embodiment. A method of forming an integrated circuit may comprise forming memory cells and forming segments of lines of a rewiring layer. The segments of lines of the rewiring layer may extend in a direction which is slanted with respect to a first direction. Moreover, the method may comprise forming bit line contacts. The bit lines contacts may be arranged in a checkerboard pattern with respect to the first direction. According to an embodiment, the method may further comprise defining gate electrodes in a support portion, wherein the gate electrodes in the support portion may comprise a layer of the rewiring layer. For example, the gate electrodes in the support portion may be processed before or after defining the segments of lines of the rewiring layer in the array portion. As a further alternative, the gate electrodes in the support portion and the segments of lines of the rewiring layer may be formed by common processing steps.

FIG. 8 shows an example of a substrate when performing the method of the invention. For example, isolation trenches 12 may be formed in a substrate having a surface 10. By way of example, the isolation trenches 12 may be formed so as to extend as parallel lines. For example during the formation of the isolation trenches 12, specific lithographic methods may be employed so as to obtain a smaller line width than that is achievable with the technology employed. For example, any kind of pitch fragmentation of double patterning may be employed. By way of example, a pitch of the isolation trenches may be 4F, wherein F denotes the minimal structural feature size which may be obtained by the technology employed. The pitch corresponds to the sum of line width and line distance. For example, F may be 115 nm, 95 nm, or less than 80 nm. For example, F may be even less than 70 nm, for example, 55 nm n or even less than 40 nm. After defining the isolation trenches in the substrate surface 10, the isolation trenches 12 may be filled with an appropriate insulating material or a combination of different insulating materials such as silicon oxide, silicon nitride and others. FIG. 8 shows a plan view of an example of a substrate. For example, isolation trenches 12 may be formed, active area lines 11 of the substrate material being formed between adjacent isolation trenches 12. After forming the isolation trenches, several implantation steps may be performed so as to provide the doped portions where necessary. For example, well implantation steps and device implantation steps may be performed, for example, so as to form the doped source/drain portions.

Thereafter, several layers so as to establish a hard mask layer stack may be formed over the substrate. For example, the hard mask layer stack may comprise material layers which may also be used in the support portion or the completed memory device. As an example, the hard mask layer stack may first comprise a silicon oxide layer 61 having a thickness of approximately 1 to 10 nm. The silicon oxide layer 61 may act as a gate oxide layer in the support portion, followed by a polysilicon layer 62 which may have a thickness of approximately 10 to 100 nm. The polysilicon layer 62 may be used as a conductive gate layer in the support portion. Thereafter, by way of example, a silicon nitride layer 63 may be formed, followed by a carbon layer 64. The silicon nitride layer 63 may have a thickness of 10 to 100 nm and the carbon layer 64 may have a thickness of 50 to 300 nm. The carbon layer may be made of elemental carbon, for example, carbon which is not contained in a specific compound. Thereafter, for example, the hard mask layer stack may be patterned, for example, using a mask having a lines/spacers pattern. For example, the hard mask layer stack 64b may be patterned so as to obtain lines 64a which extend in the first direction 13. For example, the hard mask lines 64a may extend perpendicularly with respect to the direction of the isolation trenches 12.

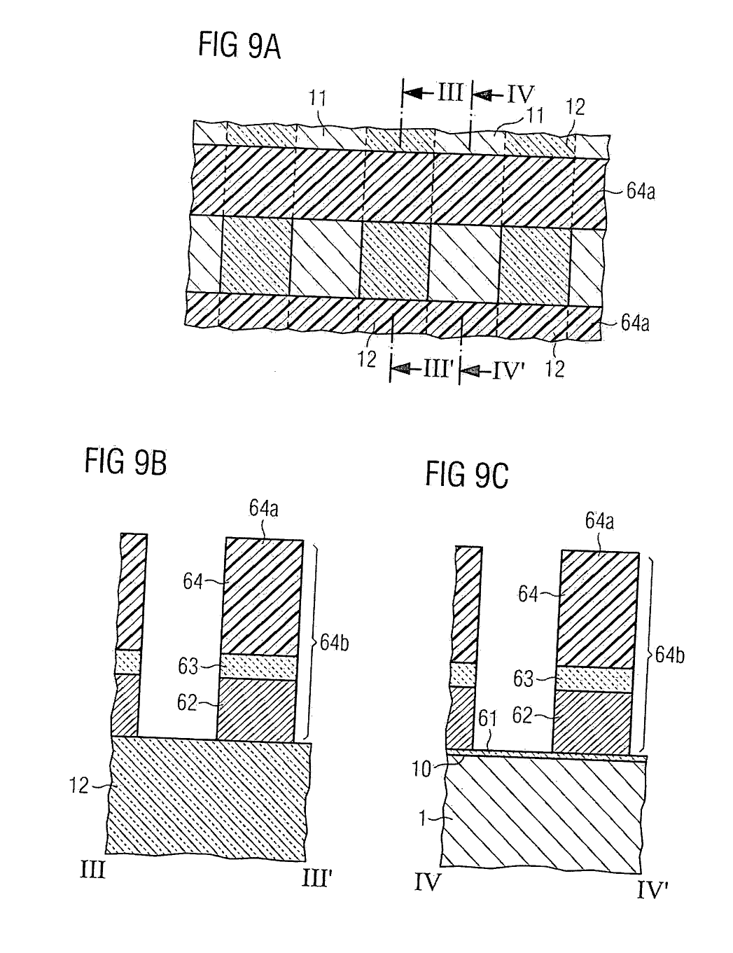

FIG. 9A shows an example of a plan view of the resulting structure. As can be seen, the hard mask lines 64a extend so as to intersect the isolation trenches 12. Moreover, FIGS. 9B and 9C shows cross-sectional views of the substrate. For example, the cross-sectional view of FIG. 9B is taken between III and III′ as is shown in FIG. 9A. To be more specific, the cross-sectional view of FIG. 9B is taken along an isolation trench 12. Moreover, the cross-sectional view of FIG. 9C is taken between IV and IV′. As can be seen, the cross-sectional view of FIG. 9C is taken along an active area line 11.

Thereafter, a silicon oxide spacer 65 may be formed. For example, the spacer 65 may be formed by conformally depositing a silicon oxide layer followed by an anisotropic etching step so as to remove the horizontal portions of the silicon oxide layer. By adjusting the thickness of the sacrificial spacers 65, the width of grooves in which the first and second gate electrodes are to be formed may be determined. For example, silicon oxide may be taken as the material of the sacrificial spacer 65.

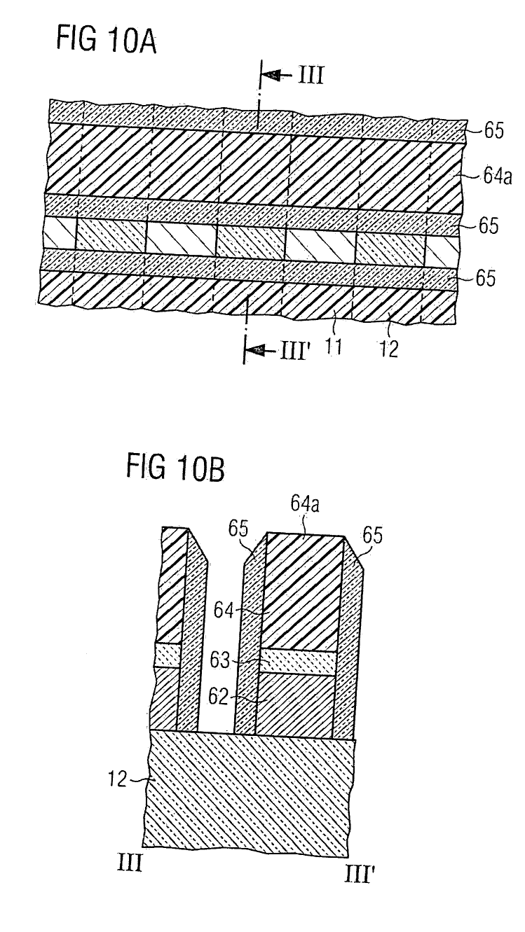

FIG. 10A shows a plan view of an example of the resulting structure. FIG. 10B shows a cross-sectional view of an example of the resulting structure. Thereafter, optionally, a sacrificial fill 66 may be provided, followed by a back-etching step. For example, silicon nitride may be taken as the material of the sacrificial fill 66.

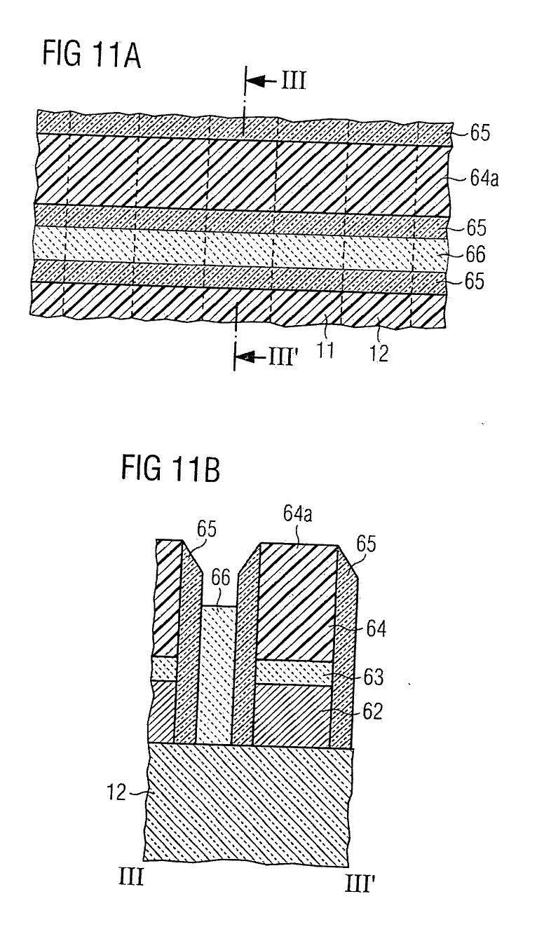

FIG. 11A shows an example of a plan view of the resulting structure. Moreover, FIG. 11B shows a cross-sectional view between III and III′ of the structure. As can be seen, the space between adjacent sacrificial spacers 65 is filled with the sacrificial fill 66. Thereafter, the sacrificial spacers 65 may be removed, leaving a space between the sacrificial fill 66 and the adjacent hard mask lines 64a.

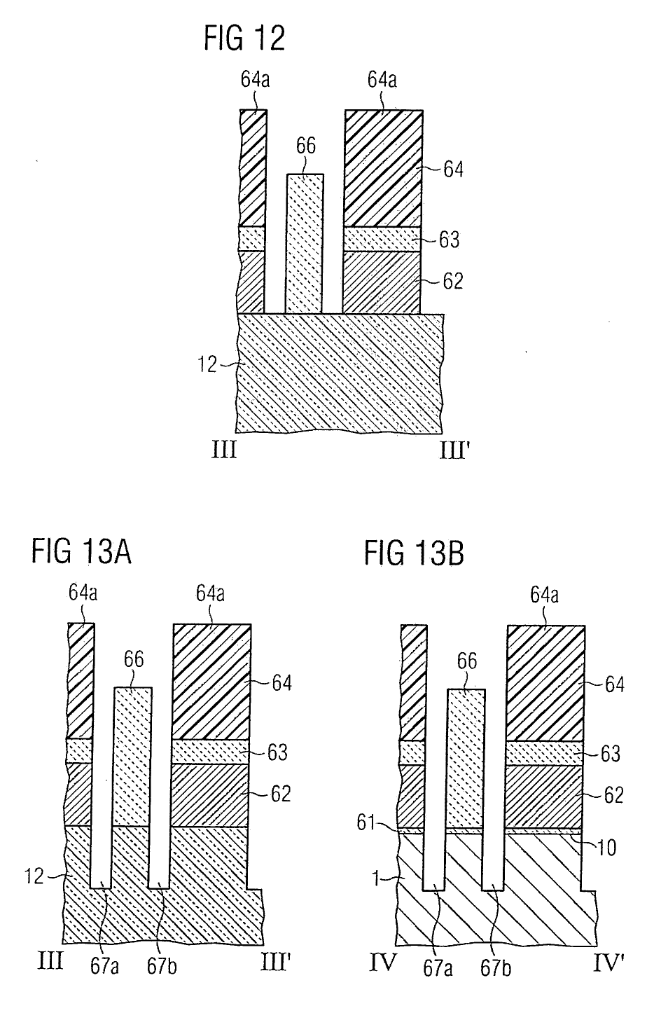

FIG. 12 shows an example of a cross-sectional view between III and III′. Thereafter, an etching step is performed so as to etch substrate material and silicon oxide. Accordingly, taking the patterned hard mask lines 64 as well as the sacrificial fill 66 as an etching mask, first and second gate grooves 67a, 67b are formed. The first and second gate grooves 67a, 67b are formed so as to extend in the substrate material as well as in the isolation trenches 12.

Cross-sectional views of example of resulting substrates are shown in FIGS. 13A and 13B. For example, as is shown in the cross-sectional views shown in FIGS. 13A and 13B, the gate grooves 67a and 67b extend in the substrate material as well as in the isolation trenches 12.

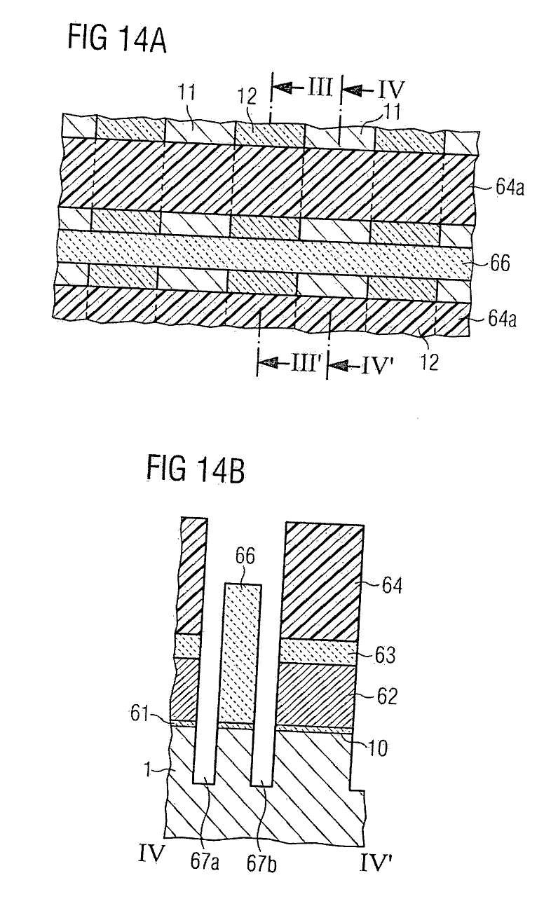

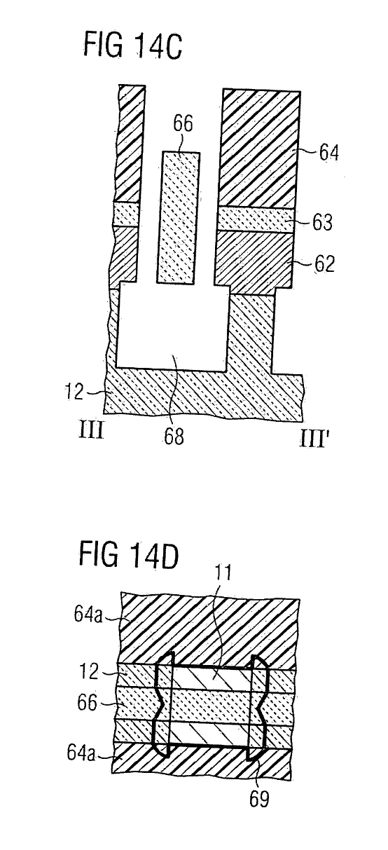

Thereafter, optionally, silicon oxide may be etched while the substrate material is substantially maintained. As a result, a word lane groove 68 may be formed in the isolation trenches 12 between adjacent active area lines 11. FIG. 14 shows various views of an example of a resulting substrate. For example, FIG. 14A shows a plan view of the resulting structure. Moreover, FIG. 14B shows a cross-sectional view between IV and IV′ which remains unchanged with respect to the cross-sectional view shown in FIG. 13B. Moreover, as shown in FIG. 14C showing a cross-sectional view between III and III′, the silicon oxide material between adjacent gate grooves 67a, 67b may be removed in the isolation trenches 12. In addition, FIG. 14D shows a schematical view of the locations at which vertical portions of the gate electrode have been formed in the isolation trenches 12. Accordingly, optionally, so-called corner devices have been formed at the indicated locations.

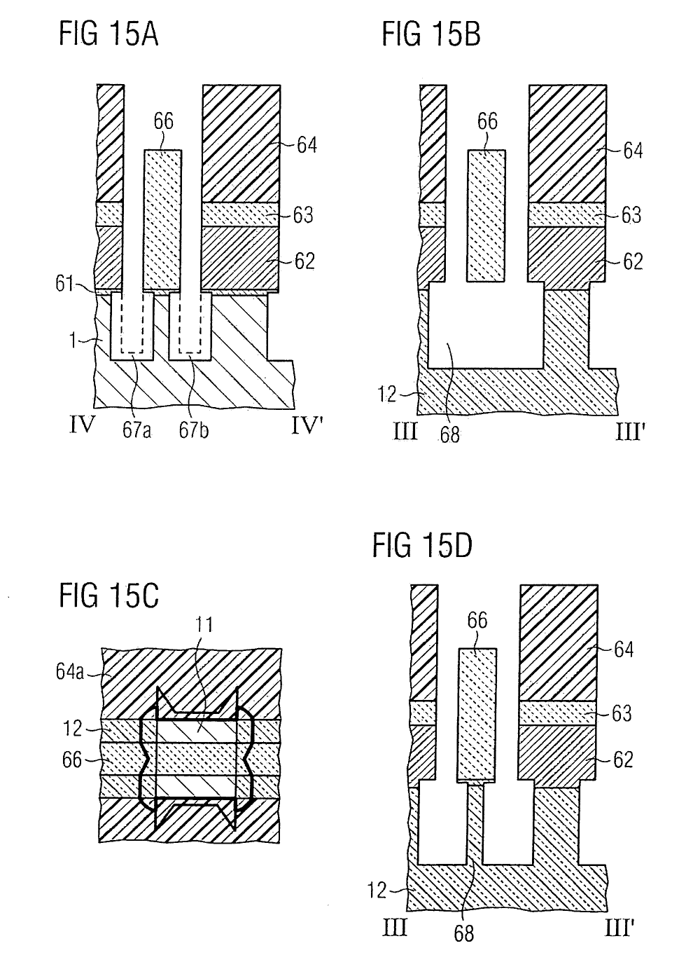

Thereafter, optionally, silicon may be etched, for example, by an isotropic etching. Due to this etching step, for example, the first and the second gate grooves 67a, 67b may be enlarged, leaving a narrowed source/drain portion in between. FIG. 15A shows a cross-sectional view which is taken along an active area portion. As is shown, due to the isotropic Si etching step, the grooves 67a, 67b are widened. Moreover, as is shown in the cross-sectional view between III and III′ which is shown in FIG. 15B, in the isolation trenches 12, the gate groove or word line groove remains unaffected. As is shown in the plan view shown in FIG. 15-C, the gate grooves 67a, 67b extend wider into the substrate portion.

FIG. 15D shows a modification of the view shown in FIG. 15B. This Figure shows a cross-sectional view of the substrate which may be obtained in a case in which the first and second gate electrodes 55a, 55b form part of two adjacent word lines 58a, 58b.

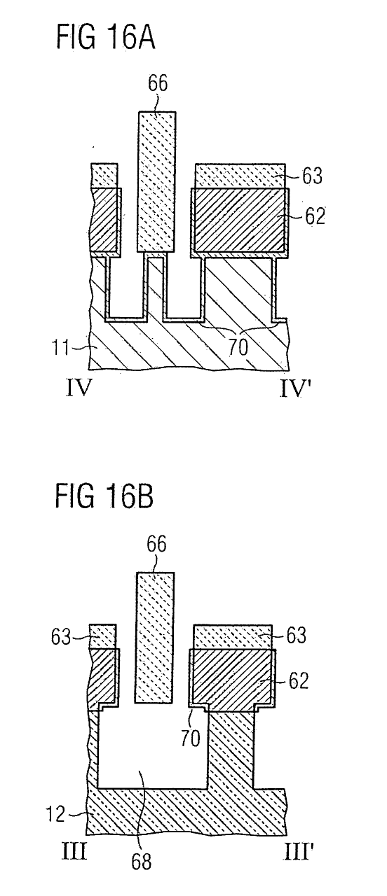

Thereafter, the upper portion of the hard mask layer stack 64b may be removed. For example, the carbon hard mask layer 64 may be removed. Then, a suitable gate dielectric layer 70 is provided. For example, a silicon oxide layer may be formed by performing an oxidation step. FIGS. 16A and 16B show various cross-sectional views of an example of a resulting substrate. As shown in FIGS. 16A and 16B, the gate dielectric layer 70 is provided so as to be disposed on the bottom surface of the gate grooves 67a, 67b. Moreover, the gate dielectric layer 70 is disposed on the vertical side walls of the hard mask layer 62.

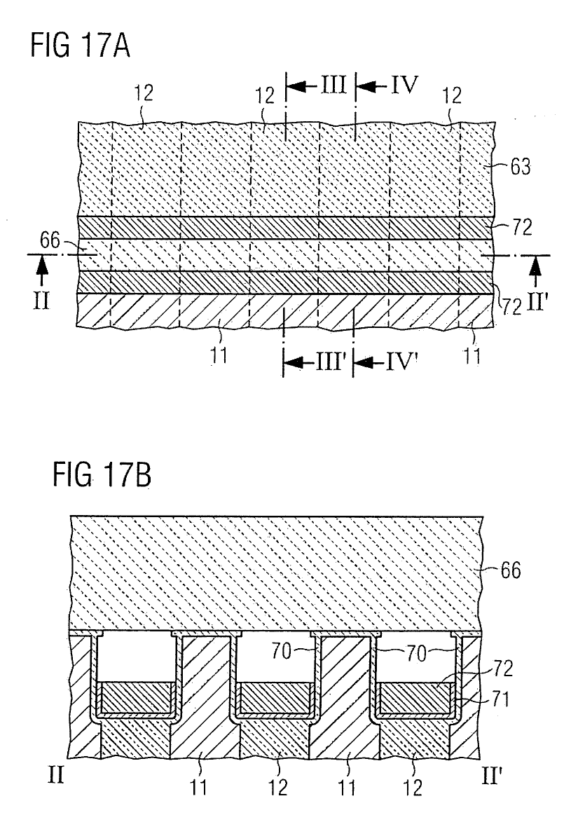

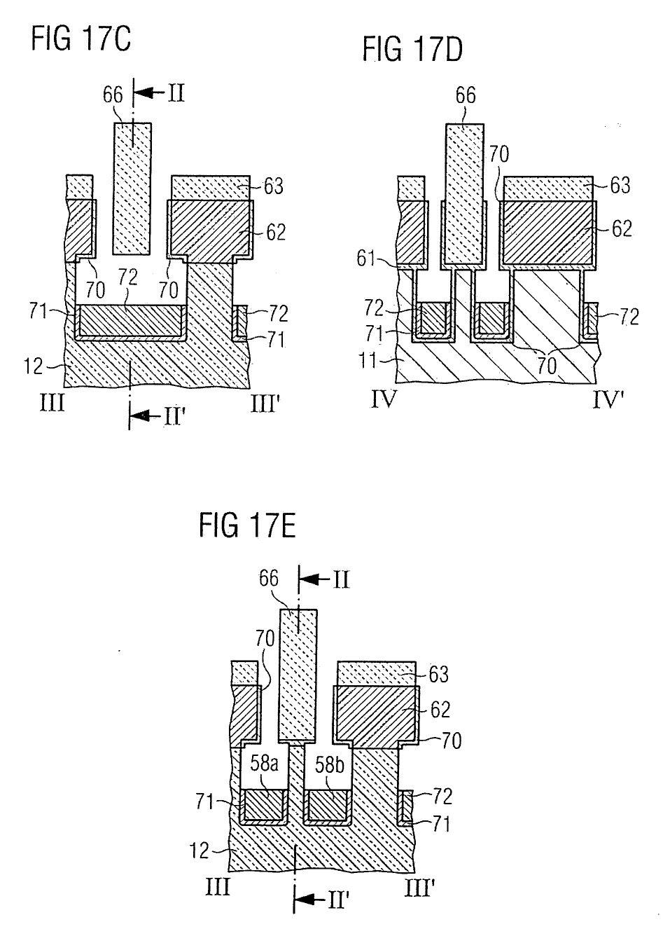

Thereafter, a gate conductive material is provided. The gate conductive material may form the word lines as well as the gate electrodes of the transistors in the array portion is provided. By way of example, a titanium nitride liner may be deposited, followed by a tungsten layer. For example, the TiN liner may have a thickness of approximately 1 to 10 nm. After depositing the tungsten layer, optionally, a planarization step may be performed, which may be followed by a recess etching step. For example, the surface of the tungsten layer may be recessed to a level of 20 to 120 nm below the substrate surface level 10. For example, the depth of the word line grooves may be 120 to 1.40 nm, measured from the substrate surface 10. Then, the uncovered portions of the TiN layer may be removed by a suitable etching step. FIGS. 17A to 17D show various views of an example of a resulting structure.

FIG. 17E shows a modification of the view shown in FIG. 15C. This Figure shows a cross-sectional view of the substrate which may be obtained in a case in which the first and second gate electrodes 55a, 55b form part of two adjacent word lines 58a, 58b.

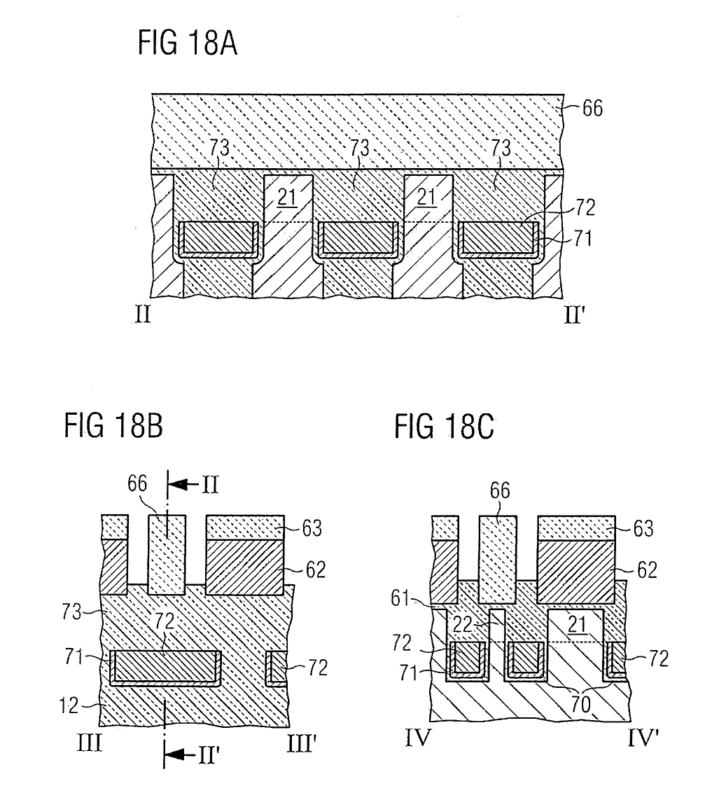

Thereafter, a suitable dielectric layer 73 may be provided. For example, a silicon oxide layer 73 may be formed so as to cover the gate conductive material. Thereafter, a suitable polishing step, for example, a CMP step may be performed and the height of the dielectric layer 73 may be adjusted so that the surface is disposed above the substrate surface 10, for example. FIGS. 18A to 18C show various cross-sectional views of an example of a resulting substrate.

Thereafter, the remaining portions of the first hard mask layer 63 as well as of the sacrificial fill 66 may be removed. Then, an ion implantation step may be performed so as to provide the first and second source/drain portions of the transistor to be formed. For example, these implantation steps may be performed in a manner as is conventional so as to provide the corresponding dopants. Moreover, the uncovered portions of the gate dielectric layer 70 may be removed, for example, by performing an oxide deglazing step. Then, a further polysilicon layer may be deposited, followed by a suitable planarization step so as to obtain a planar surface. Thereafter, further layers for constituting a rewiring layer are deposited. For example, the rewiring layer may comprise several conductive layers, followed by a dielectric layer. According to an embodiment, the rewiring layer may comprise the same layers as the gate conductive layers for the support portion. Accordingly, several layers having a double function may be deposited. For example, in she array portion, the deposited layers may act as a rewiring layer. Moreover, in the support portion, the conductive layers may act as the gate conductive layers. Then, the gate conductive layers may be patterned using a commonly used patterning method. For example, the rewiring layer may be patterned using a photolithographic method using a photomask having a lines/spaces pattern. For example, the lines and spaces of the photomask may extend in a direction which is slanted with respect to the first direction 13 and the second direction 14. After photolithographically patterning the conductive layer stack, an etching step may be performed so as to obtain corresponding lines.

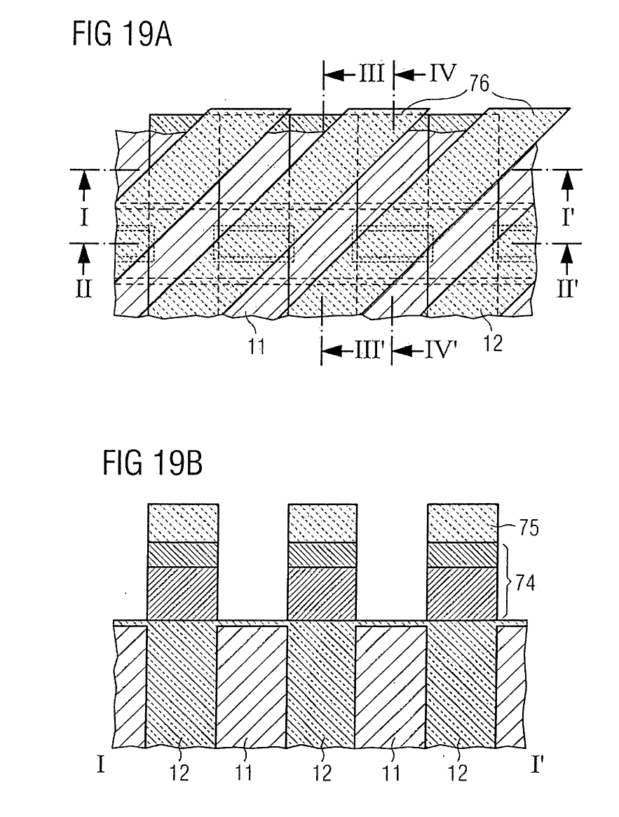

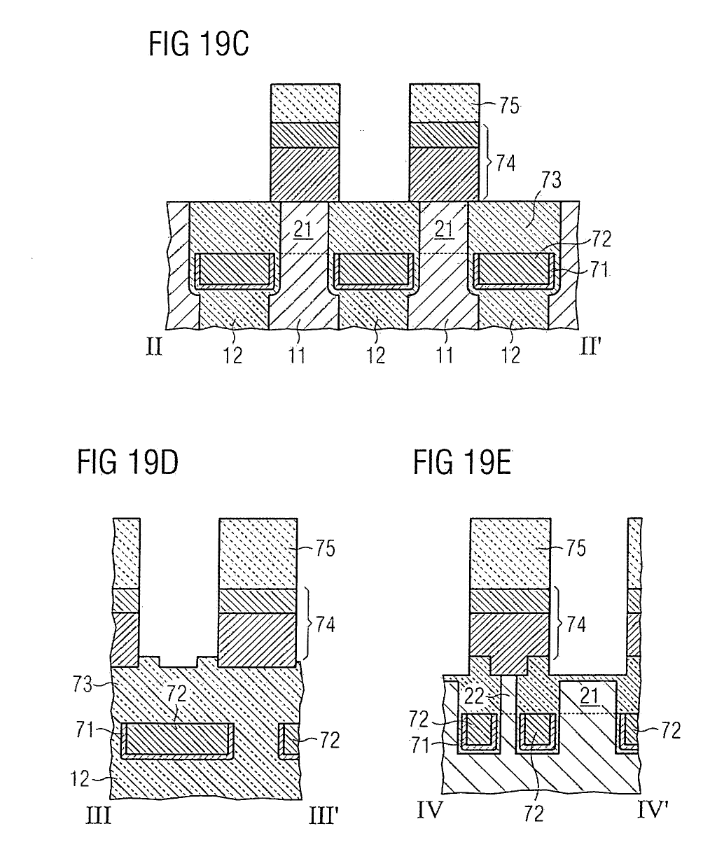

FIGS. 19A to 19E show various views of an example of a substrate after these processing steps. As is shown in FIG. 19A showing a plan view of the resulting structure, hard mask lines 76 are formed. The hard mask lines 76 extend in a direction which is slanted with respect to the first and second direction. As is shown in the cross-sectional view between I and I′ which is shown in FIG. 19B, due to the special pattern of the hard mask lines 76 and the lines of the conductive layer stack 74, the active areas 11 are uncovered along a line which is shifted with respect to the bit lines. Moreover, as is shown in FIG. 19C showing a cross-sectional view between II and II′, the conductive line stack 74 is disposed at a location between adjacent isolation trenches 12. FIG. 19D snows a cross-sectional view between III and III′. Moreover, as is shown in the cross-sectional view between IV and IV′ which is shown in FIG. 19E, the conductive layer stack 74 is adjacent to the second source/drain portion 22. Moreover, no conductive layer stack 74 is adjacent to the first source/drain portion 21. Thereafter, the devices in the support portion may be further processed. For example, the conductive layer stack may be processed so as to form gate electrodes in the support portion. Nevertheless, further processing steps may be performed. Moreover, a silicon nitride layer may be deposited, followed, by an anisotropic etching step. Due to this anisotropic etching step, spacers are formed so as to be adjacent to the gate electrodes in the support portion. Moreover, a planar silicon nitride layer 77 may be formed in the array portion.

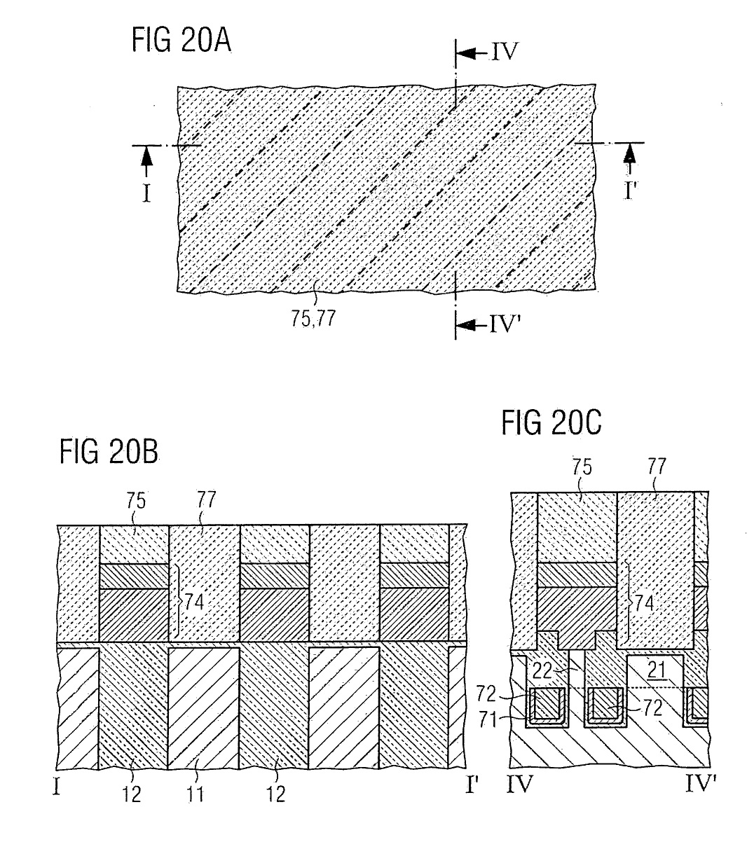

As a result, the whole array portion is covered by the silicon nitride layer 75, 77, as is for example shown in FIG. 20A showing a plan view. Moreover, as shown in FIGS. 20B and 20C, silicon nitride lines 75 are formed on top of the conductive layer stack 74, and silicon nitride lines 77 are formed between lines of the conductive layer stack 74.

Thereafter, various further processing steps may be performed in the support portion. For example, dielectric layers may be deposited, followed by suitable back-etching or planarization steps. For example, a spin-on-glass may be deposited as an interlayer dielectric and a CMP step to the gate electrode may be performed. Optionally, also self-aligned contacts in the support portion may be formed as is conventional.

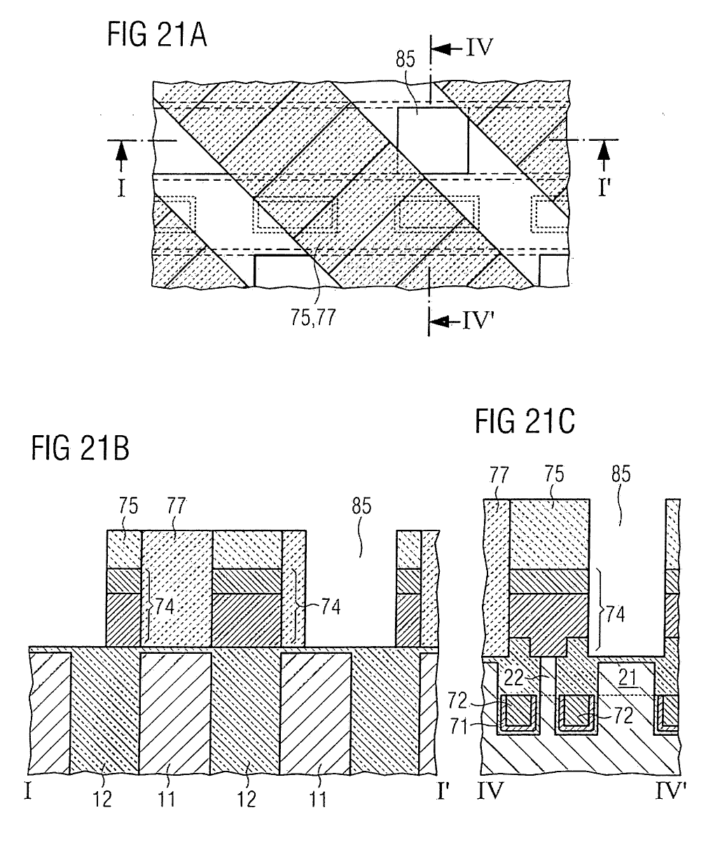

Thereafter, segments of lines may be formed by patterning the silicon nitride hard mask 75, 77 and interrupting the lines or the conductive layer stack 74. For example, the silicon nitride layer may be patterned using a mask having a lines/spacers pattern. For example, this lines/spaces pattern may be rotated by 90° with respect to the lines/spaces pattern which has been used for patterning the lines 76 shown in FIG. 19A. After correspondingly patterning the silicon nitride hard mask 75, 77, an etching step is performed so as to interrupt the lines of the conductive layer stack 74. By this etching step, also the bit line contact openings 85 may be defined. As can, for example, be seen in FIG. 21A, portions of the substrate surface are exposed. Accordingly, as is shown in FIG. 21B which shows a cross-sectional view between I and I′, at a predetermined portion a bit line contact opening 85 is formed. As can be seen, the surface of this active area 11 is covered by the support gate dielectric layer which was formed by a former processing step. Moreover, as is shown in the cross-section-al view between IV and IV′, in FIG. 21C the bit line contact opening 85 is formed so as to be in contact with the first source/drain portion 21.

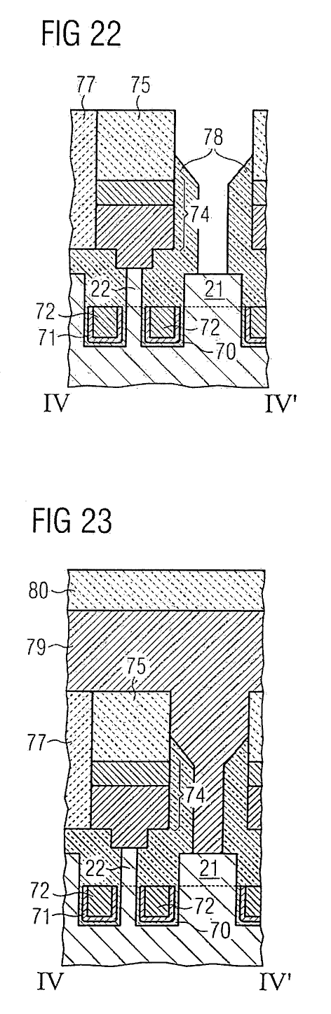

Thereafter, a further silicon oxide layer may be deposited, followed by an anisotropic etching step. By these processing steps, a spacer 78 may be formed so as to be adjacent to the conductive lines 74. Moreover, due to this etching step, the surface of the first source/drain portion 21 is uncovered. An example of a resulting structure is shown in FIG. 22.

Thereafter, the further processing steps which are commonly used may be performed. By way of example, the bit lines may be formed. This may be accomplished, by first depositing a suitable liner layer such as TiN, followed by a suitable metal layer. For example tungsten may be taken as the conductive material constituting the bit lines. Nevertheless, as is obvious to the person skilled in the art, any other material or material combination may be used for forming the bit lines. Thereafter, a suitable dielectric layer 80 may be formed over the conductive material. For example, a silicon nitride layer may be taken as the cap layer 80. Then, a lithographic step may be performed so as to pattern the single conductive lines 79. For example, a photolithographic process using a photomask having lines/spaces pattern may be employed. A cross-sectional view of an example of a resulting structure is shown in FIG. 23.

As is shown, the conductive lines 79 are formed so as to be in direct contact with a first source/drain portion 21. A cap layer 80 is formed over the conductive line 79. Then, as is common, a bit line spacer may be formed. For example, a silicon nitride layer may be deposited, followed by an anisotropic etching step. As a result, silicon nitride spacers 81 may be formed so as to be adjacent to the vertical side walls of the bit lines 79.

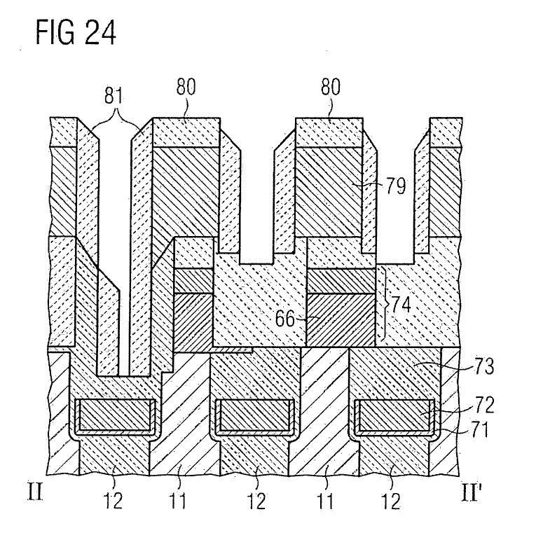

A cross-sectional view of an example of a resulting structure is shown in FIG. 24. As can be seen, now the bit lines 79 are encapsulated by the silicon nitride material 80, 81. Thereafter, further processing steps so as to provide storage capacitors may be performed. By way of example, several dielectric layers may be formed so as to provide the interlayer dielectric for the M0 metallization layer. A CMP step to the nitride gate layer may be performed. Thereafter, a photolithographic seep may be performed so as form openings for defining the capacitor contacts. The openings may be formed so as to be in contact with the conductive layer stack 74. Then, capacitor contacts may be formed in a conventional manner.

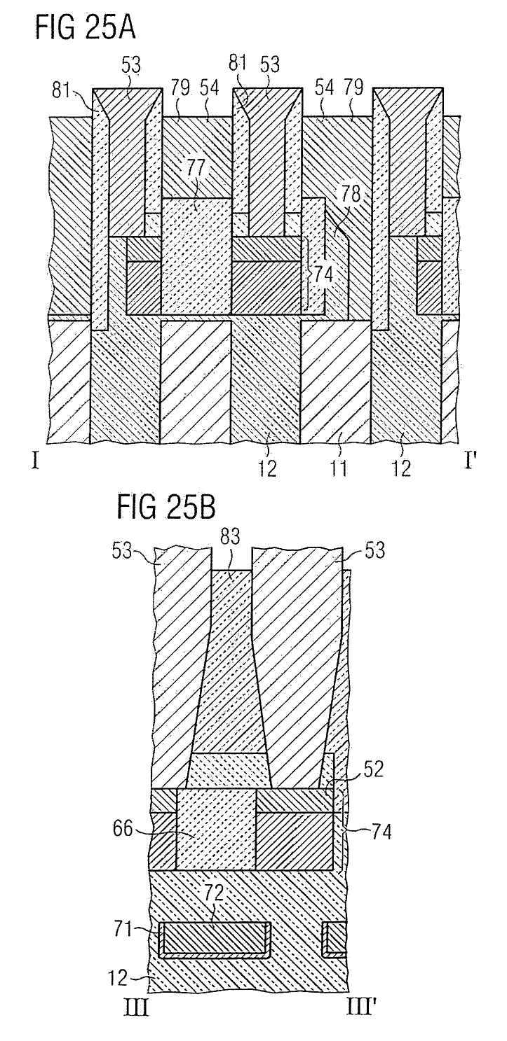

A cross-sectional view of an example of the resulting structure is shown in FIGS. 25A and 25B, respectively. To be more specific, the cross-sectional views shown in FIGS. 25A and 25B correspond to the views shown in FIGS. 21B and 21C, respectively, wherein the storage capacitors 82 are omitted. As can be seen, the capacitor contacts 53 are in contact with the conductive layer stack 74. Accordingly, an electrical contact is established by the conductive layer stack between the capacitor contacts 53 and the second source/drain portion 22. Adjacent capacitor contacts 53 are insulated from each other by the insulating material 83. Thereafter, the storage capacitors are formed in a conventional manner.

The description above is an example and is shown not to limit the scope and/or the spirit of the invention that is defined by the appended claims.

1. An integrated circuit including a memory cell array, the integrated circuit comprising:
word lines extending in a first direction;
bit lines extending in a second direction intersecting the first direction;
memory cells having storage elements;
bit line contacts in signal connection with a memory cell and a corresponding bit line,
wherein the bit line, contacts are arranged in a checkerboard pattern with respect to the first direction, and
the storage elements are arranged in a regular grid along the first and second directions, respectively.

2. The integrated circuit of claim 1,
wherein the memory cells have transistors, the transistor including a first and a second source/drain portions,
wherein sections of a rewiring layer are disposed so as to connect one of the storage elements with a corresponding first source/drain portion.

3. The integrated circuit of claim 2, further comprising
a capacitor contact that is disposed between the storage element and the section of the rewiring layer.

4. The integrated circuit of claim 2, wherein the sections of the rewiring layer are segments of parallel lines.

5. The integrated circuit of claim 2, wherein the sections of the rewiring layer are segments of parallel lines extending in a direction intersecting the first and second directions.

6. The integrated circuit of claim 2, wherein the bit lines are disposed in a layer lying over the rewiring layer.

7. The integrated circuit of claim 1, wherein the bit lines are disposed in a layer lying over the bit line contacts.

8. The integrated circuit of claim 7, wherein the bit lines and the bit line contacts are made of the same material.

9. An integrated circuit including a memory cell array, the integrated circuit comprising:
bit lines extending in a second direction;
memory cells having transistors, each of the transistors including a channel including a directional component extending along a second direction,
capacitor contacts in signal connection with the transistor and a corresponding storage element,
wherein the capacitor contacts are arranged in a regular grid along the second direction.

10. The integrated circuit of claim 9, wherein each of the transistors comprises:
a first and a second source/drain portions;
a first gate electrode disposed adjacent to a substrate portion between the first and second source/drain portions; and
a second gate electrode that is in contact with the first gate electrode, wherein the first and the second gate electrode are arranged on opposite sides with respect to the first source/drain portion.

11. The integrated circuit of claim 9, wherein each of the transistors comprises:
a first and a second source/drain portions; and
a gate electrode adjacent to the channel,
wherein in a cross-sectional view along the second direction the gate electrode is adjacent to two opposite sides of the channel.

12. The integrated circuit of claim 9, wherein a first transistor is disposed adjacent to a second transistor, wherein each of the transistors comprises:
a first and a second source/drain portions;
a first gate electrode disposed between the first and the second source/drain portions; and
a second gate electrode which is disposed between the first source/drain portion of the first transistor and the second source/drain portion of the second transistor, wherein
the first and the second gate electrode are in contact with each other.

13. An integrated circuit including a memory cell array, the integrated circuit comprising:
word lines; and
node contacts, wherein
adjacent word lines are insulated from each other and the word lines include slotted portions, in which the word lines comprise a first and a second portion, the first and the second portions being disposed on opposite sides of a corresponding node contact, respectively.

14. The integrated circuit of claim 13, wherein the word lines extend in a first direction, the integrated circuit further comprising
bit lines extending in a second direction, wherein the memory cell array comprises transistors disposed in active areas extending in the second direction.

15. The integrated circuit of claim 13, wherein the node contacts are arranged in a regular grid.

16. An integrated circuit including a memory cell array, the integrated circuit comprising:
word lines; and
node contacts, wherein
adjacent word lines are isolated from each other, and two adjacent word lines are configured to be held at the same potential, the two adjacent word lines being disposed on opposite sides of a corresponding node contact, respectively.

17. The integrated circuit of claim 16, wherein the word lines extend in a first direction, the integrated circuit further comprising bit lines extend ing in a second direction, wherein the memory cell array comprises transistors disposed in active areas extending in the second direction.

18. The integrated circuit of claim 16, wherein the node contacts are arranged in a regular grid.

19. An integrated circuit including a memory device comprising:
a memory cell array; and
a support portion,
wherein the support portion includes transistors having a gate electrode,
wherein the array portion includes a rewiring layer for connecting transistors with storage elements, and
wherein at least a portion of the rewiring layer and at least a portion of the gate electrodes are made from the same layer.

20. A method of manufacturing an integrated circuit comprising:
forming memory cells;
forming bit line contacts that are arranged in a checkerboard pattern with respect to a first direction; and
forming segments of lines of a rewiring layer extending in a direction that is slanted with respect to the first direction.

21. The method of claim 20, further comprising
defining gate electrodes in a support portion,
wherein the gate electrodes in the support portion are made of the rewiring layer.
